(19) United States
(12) Patent Application Publication
(10) Pub. No.: US 2025/0047290 A1
(43) Pub. Date: Feb. 6, 2025

(54) RESONATOR AGING TRACKING

(71) Applicants: Renzhi Liu, Portland, OR (US); Sarah Shahraini, Santa Clara, CA (US); Timo Huusari, Hillsboro, OR (US); Richard Dorrance, Hillsboro, OR (US); Charles Augustine, Portland, OR (US); Brent R. Carlton, Portland, OR (US)

(72) Inventors: Renzhi Liu, Portland, OR (US); Sarah Shahraini, Santa Clara, CA (US); Timo Huusari, Hillsboro, OR (US); Richard Dorrance, Hillsboro, OR (US); Charles Augustine, Portland, OR (US); Brent R. Carlton, Portland, OR (US)

(21) Appl. No.: 18/230,294

(22) Filed: Aug. 4, 2023

(51) Int. Cl. H03L 7/24; G04F 5/04

(52) U.S. Cl. CPC H03L 7/24; G04F 5/04

(57) ABSTRACT

Some embodiments include a first oscillator circuit including a first input node to receive a connection from a first resonator, and a first output node to provide a first oscillating signal; a second oscillator circuit including a second input node to receive a connection from a second resonator, and a second output node to provide a second oscillating signal; a frequency measurement circuit coupled to the first output node and the second output node; a code generator including an input node coupled to an output node of the frequency measurement circuit, and an output node to provide a code; and a timing signal generator including a node coupled to the output node of the code generator, an input node coupled to the output node of the first oscillator circuit, an output node to provide an output oscillating signal.

### TECHNICAL FIELD

Embodiments described herein pertain to timing signal generations in electronic devices and systems. Some embodiments relate to oscillator circuitry.

### BACKGROUND

Most electronic devices or systems use timing signals (e.g., clock signals) to control timing of many of their operations. Such timing signals are normally generated by resonator circuits. The timing signals are often generated with a specific frequency depending on operational specifications of the device or system. A typical resonator circuit includes a resonator and circuit elements (e.g., transistors and capacitors) combined to generate timing signals. Examples of popular resonators include quartz crystals and ceramic. In some devices or systems (e.g., those used in communication and positioning systems), high-precision timing is a critical aspect. A resonator circuit that includes quartz crystals and ceramic can be used to provide such high-precision timing. However, due to aging of the resonator, timing signals generated by the resonator circuit may deviate from their intended value. For example, the frequency of the timing signals may change (e.g., drift) over time. Some conventional techniques try to avoid this aging condition by periodically synchronizing the device to timing of global positioning system (GPS) or to a local atomic clock. However, reliance on GPS creates significant constraints on high-precision timing applications. For example, the local timing accuracy of a device may be lost in indoor or in other environments where the device may be off-line. Alternatively, a stable local timing solution such as a local atomic clock may be used. However, using such a local atomic clock can significantly increase cost of the device or system.

### BRIEF DESCRIPTION OF THE DRAWINGS

FIG. 1 shows an apparatus including a device and resonators, according to some embodiments described herein.

FIG. 2 shows active and inactive time intervals associated with duty-cycle operations of resonator oscillators of the device of FIG. 1, according to some embodiments described herein.

FIG. 3 shows an apparatus in the form of a system, according to some embodiments described herein.

FIG. 4 is a flowchart showing a method of tracking aging of a resonator oscillator, according to some embodiments described herein.

### DETAILED DESCRIPTION

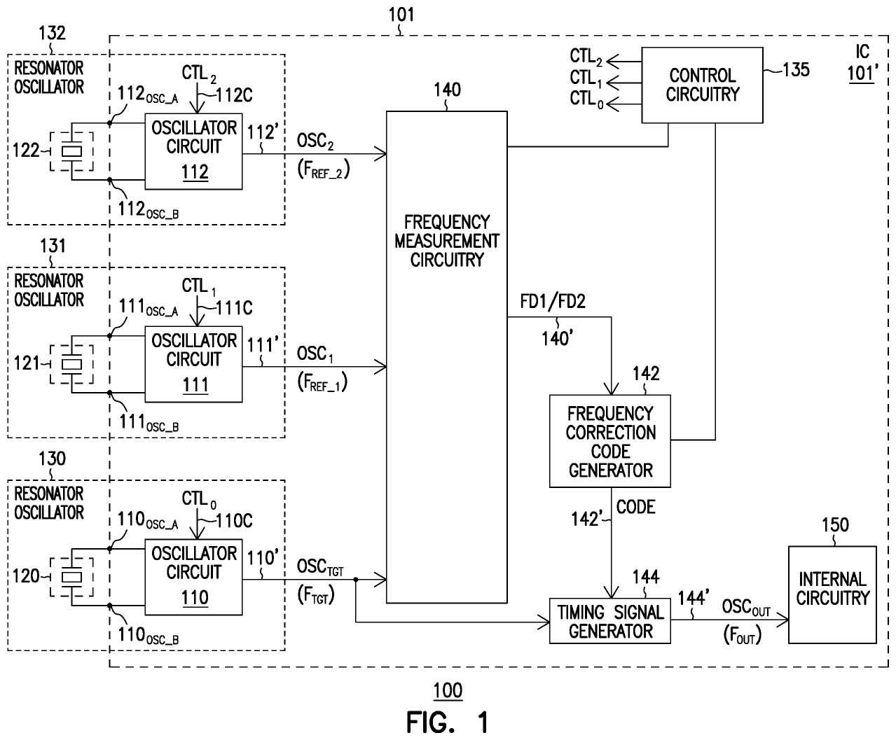

The techniques described herein involve apparatus and methods for maintaining the accuracy of timing in electronic devices and systems without relying on GPS or local atomic clocks. The techniques described involve tracking aging of a main resonator oscillator included in an electronic apparatus (e.g., device or system or both) and correcting the frequency of a timing signal that is generated based on an oscillating signal provided by the main resonator oscillator. The techniques described herein exploit the phenomenon that the rate of aging of a resonator oscillator is proportional to the time it is active (e.g., in use). For example, the more active the resonator oscillator, the faster it ages. To track aging of the main resonator oscillator, the described apparatus also includes additional resonator oscillators that can be used as reference resonator oscillators. The additional resonator oscillators are not used to generate signals for use as clock signals in the apparatus. They are used to track aging of the main resonator oscillator. The described techniques provide a low-cost solution to maintain accuracy of timing signal in the apparatus. These and other improvements and benefits of the described techniques are discussed in more detail below with reference to FIG. 1 through FIG. 4.

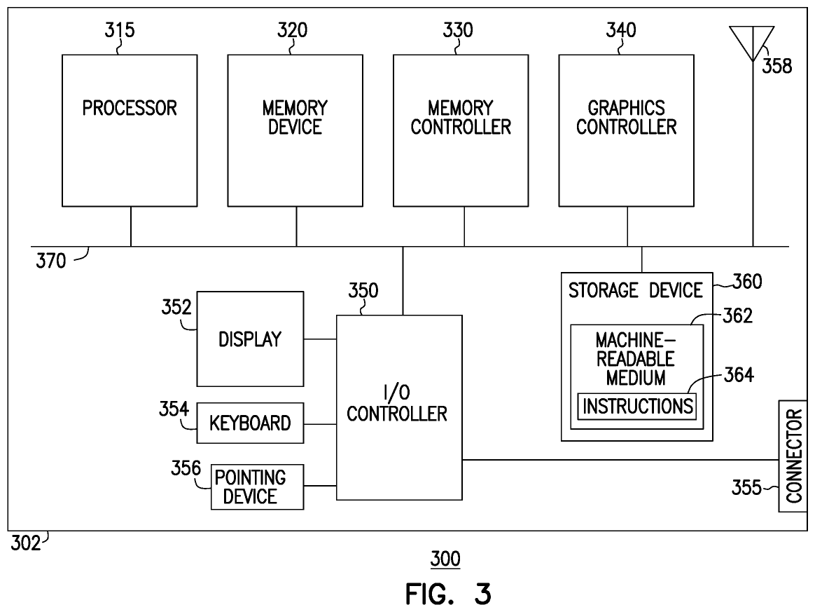

FIG. 1 shows an apparatus 100 including a device 101, according to some embodiments described herein. Apparatus 100 can include or be included in an electronic device or system, such as a computer (e.g., desktop, laptop, or notebook), a tablet, a cellular phone, a system on chip (SoC), a system in a package (SiP), or other electronic devices or systems. In an example, device 101 can include or can be included in a processor (e.g., a hardware processor) that may include a central processing unit (CPU), a graphics processing unit (GPU), or both CPU and GPU. In another example, device 101 can include a memory device, a memory controller, or other electronic devices. In another example, device 101 can be part of a SoC or alternatively, part of an SiP. As shown in FIG. 1, device 101 can include (or can be included in) an integrated circuit (IC) chip 101′. IC chip 101′ can include a semiconductor chip that can be a semiconductor die (e.g., silicon-based die). Apparatus 100 can include a circuit board (e.g., a printed circuit board (PCB), not shown, on which IC chip 101′ can be located. The circuit board of apparatus 100 can be similar to or the same as circuit board 302 of FIG. 3. In the example shown in FIG. 1, resonators 120, 121, and 122 can be located outside IC chip 101′ and on the circuit board (e.g., on circuit board 302 of FIG. 3 in which IC chip 101′ can be one of the components located on circuit board 302). In another example, resonators 120, 121, and 122 can be part of IC chip 101′.

As shown in FIG. 1, device 101 can include oscillator circuit 110, oscillator circuit 111, and oscillator circuit 112, including respective nodes (e.g., control input nodes) 110C, 111C, and 112C, respectively, to receive information (e.g., control information) CTL₀, CTL₁, and CTL₂.

Oscillator circuit 110 can include nodes (e.g., input nodes) 110_{OSC_A} and 110_{OSC_B} that are formed to receive (e.g., formed to be coupled to) a connection from a resonator 120. For example, oscillator circuit 110 can be coupled to resonator 120 through a conductive connection. The conductive connection (e.g., electrical connection) can include metal traces, solder, or other kinds of conductive connections. Oscillator circuit 110 can include a node (e.g., output node) 110′ to provide a signal OSC_{TGT}.

Oscillator circuit 111 can include nodes (e.g., input nodes) 111_{OSC_A} and 111_{OSC_B} that are formed to receive (e.g., formed to be coupled to) a connection from a resonator 121. For example, oscillator circuit 111 can be coupled to resonator 121 through a conductive connection. The conductive connection (e.g., electrical connection) can include metal traces, solder, or other kinds of conductive connections. Oscillator circuit 111 can include a node (e.g., output node) 111′ to provide a signal OSC₁.

Oscillator circuit 112 can include nodes (e.g., input nodes) 112_{OSC_A}, 112_{OSC_B} that are formed to receive (e.g., formed to be coupled to) a connection from a resonator 122. For example, oscillator circuit 112 can be coupled to resonator 122 through a conductive connection. The conductive connection (e.g., electrical connection) can include metal traces, solder, or other kinds of conductive connections. Oscillator circuit 112 can include a node (e.g., output node) 112′ to provide a signal OSC₂.

In an example, each of resonators 120, 121, and 122 can include a quartz crystal. In another example, each of resonators 120, 121, and 122 can include a ceramic resonator. In another example, each of resonators 120, 121, and 122 can include components or circuit elements, which may include an LC circuit (tank circuit) or other resonant circuits, that can be used to generate a signal at a particular frequency (e.g., the frequency of signals OSC_{TGT}, OSC₁, OSC₂). Resonators 120, 121, and 123 can have the same structure (e.g., the same physical properties (e.g., physical dimensions) and/or the same chemical properties), such that they can be used to generate signals having the same frequency.

Resonator 120 and oscillator circuit 110 can form a resonator oscillator 130. Resonator 111 and oscillator circuit 111 can form a resonator oscillator 131. Resonator 122 and oscillator circuit 112 can form a resonator oscillator 132. As described above, resonators 120, 121, and 122 can include quartz crystals. Thus, resonator oscillators 130, 131, and 132 can be called crystal oscillators 130, 131, and 132 if resonators 120, 121, and 122 include quartz crystals.

Resonator oscillator 130 can be a target (e.g., a main) resonator oscillator to generate an oscillating signal OSC_{TGT}, which can be used by device 101 to generate another oscillating signal (e.g., a signal OSC_{OUT}). Device 101 can use signal OSC_{OUT} as a timing signal (e.g., a clock signal) for internal circuitry (e.g., internal circuitry 150) of device 101.

Resonator oscillators 131 and 132 can be reference resonator oscillators to generate signals (e.g., oscillating signals) OSC₁ and OSC₂. Device 101 may not use signals OSC₁ and OSC₂ to generate a timing signal (e.g., a clock signal) like signal OSC_{OUT}. As described below, device 101 can use signals OSC₁ and OSC₂ as to track the aging of resonator oscillator 130. Since resonator 120 is included in resonator oscillator 130, tracking aging of resonator oscillator 130 also means track aging of resonator 120. Similarly, tracking aging of resonator 120 also means tracking aging of resonator oscillator 130. If resonators 120, 121, and 122 include quartz crystals, tracking aging of resonator oscillator 130 also means tracking aging of crystal oscillator 130.

In order to use resonator oscillators 131 and 132 to track aging of resonator 120, the group of resonators 120, 121, and 122 are selected to be the same type of resonator (e.g., quartz crystals) with similar or the same properties (e.g., physical dimension). This means that resonators 120, 121, and 122 can provide signals with similar or the same profile (e.g., similar or the same frequency) as oscillator circuits 110, 111, and 112, respectively, before aging (when device 101 is new). As described below resonator oscillators 131 and 132 can form two-level references to track aging of resonator 120. FIG. 1 shows an example where apparatus 100 includes two resonator oscillators (e.g., two reference resonator oscillators) 131 and 132 for use as two reference resonator oscillators as an example. However, the aging tracking techniques described herein can be applicable to one reference resonator oscillator or more than two reference resonator oscillators. Thus, apparatus 100 can include an array of resonators (e.g., quartz crystals) to form resonator oscillators (like resonator oscillators 130, 131, and 132) in which the number of the resonators in the array can be different from three.

As shown in FIG. 1, device 101 can include control circuitry 135 that can operate to provide information (e.g., control information) CTL₀, CTL₁, and CTL₂ to control (e.g., activate (e.g., turn on) or deactivate (e.g., turn off)) oscillator circuit 110, oscillator circuit 111, and oscillator circuit 112, respectively. Information CTL₀, CTL₁, and CTL₂ can be analog or digital information. Each of information CTL₀, CTL₁, and CTL₂ can be in the form of a single signal or multiple signals. Resonator oscillators 130, 131, and 132 are activated (e.g., turned on) when oscillator circuits 110, 111, and 112, respectively, are activated (e.g., turned on). Resonator oscillators 130, 131, and 132 are deactivated (e.g., turned off) when oscillator circuits 110, 111, and 112, respectively, are deactivated (e.g., turned off).

As shown in in FIG. 1, oscillator circuits 110, 111, and 112 can include nodes (e.g., output nodes) 110′, 111′, and 112′, respectively, to provide signals OSC_{TGT}, OSC₁, and OSC₂, respectively. Signals OSC_{TGT}, OSC₁, and OSC₂ can have frequencies F_{TGT}, F_{REF_1}, and F_{REF_2}, respectively. Oscillator circuits 110, 111, and 112 can have the same structure (e.g., the same internal circuit components and connections) to generate signals OSC_{TGT}, OSC₁, and OSC₂ such that frequencies F_{TGT}, F_{REF_1}, and F_{REF_2} can have the same initial value (e.g., same initial value before resonators 120, 121, and 122 start to age (e.g., when apparatus 100 is new)). However, frequencies F_{TGT}, F_{REF_1}, and F_{REF_2} may have different initial values in some situations (e.g., due to variations in components among Resonator oscillators 130, 131, and 132). In such situations, for an aging tracking technique described herein, device 101 can perform an adjustment (e.g., one-time adjustment) in frequency correction to account for differences in the initial values of frequencies F_{TGT}, F_{REF_1}, and F_{REF_2}.

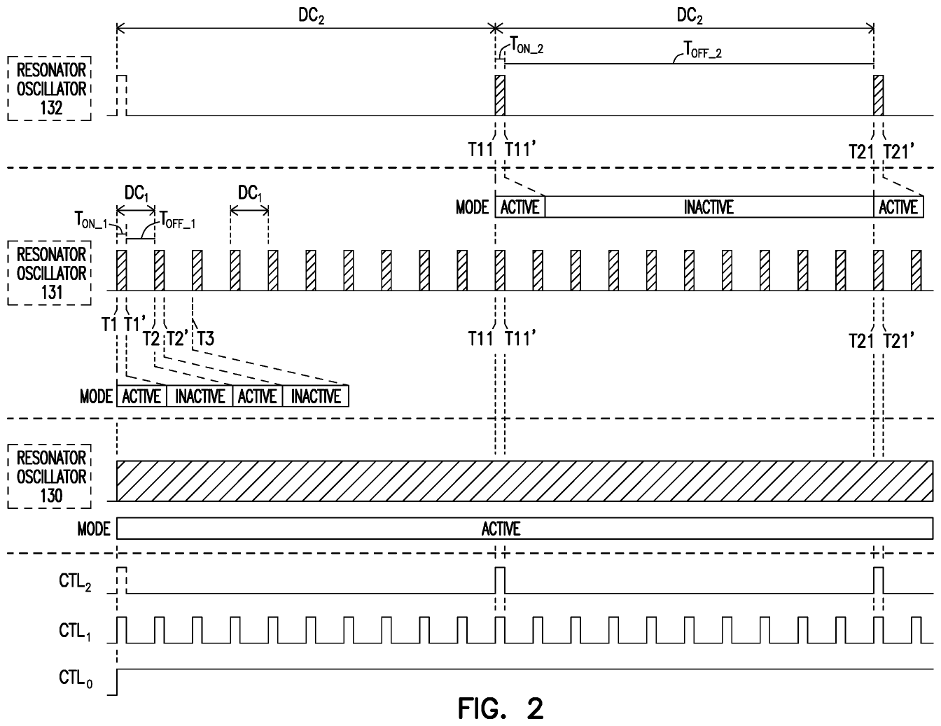

Each of resonator oscillators 130, 131, and 132 can have an active mode (e.g., active duty-cycle operation) and an inactive mode (e.g., inactive duty-cycle operation). The active and inactive modes of a respective resonator oscillator 103, 131, or 132 can be based on the value of a respective information CTL₀, CTL₁, or CTL₂. For example, resonator oscillator 130 can be in an active mode when information CTL₀ has one value and in an inactive mode when information CTL₀ has another value. Similarly, resonator oscillator 131 can be in an active mode when information CTL₁ has one value and in an inactive mode when information CTL₁ has another value. Resonator oscillator 132 can be in an active mode when information CTL₂ has one value and in an inactive mode when information CTL₂ has another value. Control circuitry 135 can be configured (e.g., can be programmed) to control (e.g., to change) the value of information CTL₀, CTL₁, and CTL₂ to activate or deactivate resonator oscillators 130, 131, and 132 (and their respective oscillator circuits 110, 111, and 112), respectively. The time intervals for activation or deactivation of resonator oscillators 130, 131, and 132 can be based on duty-cycle operation (operational duty-cycle) shown in FIG. 2 (described below with reference to FIG. 2).

In FIG. 1, during an active mode of a particular resonator oscillator (e.g., resonator oscillator 131) that particular resonator oscillator (and a respective oscillator circuit of that particular resonator oscillator) can be turned on and operating (e.g., running) to provide a respective oscillating signal (e.g., signal OSC₁) at its output node (one of nodes 110′, 111′, and 112′). During an inactive mode of a particular resonator oscillator (e.g., resonator oscillator 131) that particular resonator oscillator (and a respective oscillator circuit of that particular resonator oscillator) can be turned off and inoperative (e.g., not running), thereby not providing provide a respective oscillating signal (e.g., signal OSC₁) at its output node.

As described in detail below, resonator oscillator 130 is normally in an active mode (e.g., continuously running during operations of apparatus 100). Each of oscillator circuit 110 and oscillator circuit 111 can change (e.g., periodically change) between an active mode and an inactive mode for different time intervals based on its duty-cycle operation.

FIG. 2 is a diagram showing duty-cycle operation (active and inactive duty-cycle) of resonator oscillators 130, 131, and 132 of FIG. 1, according to some embodiments described herein. In FIG. 2, times T1 through T21 indicates different points in time. For simplicity, FIG. 2 does not show all of the times between times T1 and T21. In FIG. 2, time T1 occurs before time T2, time T3 occur before time T3, and time T3 occurs before other times (not shown). Time interval T_{ON_1} (between times T1 and T1′) indicates a time interval (measured in time units) that resonator oscillator 131 (and oscillator circuit 111) is in its active mode (e.g., turned on). For example, resonator oscillator 131 can be in an active mode between times T1 and T1′, between times T2 and T2′, between times T11 and T11′, and between times T21 and T21′. As an example, time interval T_{ON_1} can be one minute (1 min). In FIG. 2, time interval T_{OFF_1} indicates a time interval that resonator oscillator 131 (and oscillator circuit 111) is in its inactive mode (e.g., turned off). For example, resonator oscillator 131 can be in an inactive mode between times T1 and T2, and between times T2′ and T3. As an example, time interval T_{OFF_1} can be 59 minutes (59 min). Similarly, time interval T_{ON_2} indicates a time interval (measured in time units) that resonator oscillator 132 (and oscillator circuit 112) is in its active mode (e.g., turned on). For example, resonator oscillator 132 can be in an active mode between times T11 and T11′, and between times T21 and T21′. As an example, time interval T_{ON_2} can be one minute (1 min). In FIG. 2, time interval T_{OFF_2} indicates a time interval that resonator oscillator 132 (and oscillator circuit 112) is in its inactive mode (e.g., tuned off). For example, resonator oscillator 132 can be in an inactive mode between times T11′ and T21. As an example, time interval T_{OFF_2} can be one 9 hours and 59 minutes (9 hr+59 min).

Time interval T_{ON_1} can be equal to time interval T_{ON_2} (e.g., T_{ON_1}=T_{ON_2}). Alternatively, time interval T_{ON_1} can be different from (not equal to) time interval T_{ON}_2. As shown in FIG. 2, resonator oscillator 131 can be in its active mode more often than resonator oscillator 132. Thus, time interval T_{OFF_1} is less than time interval T_{OFF_2} (e.g., T_{OFF_1}<T_{OFF_2}).

As shown in FIG. 2, resonator oscillators 131 and 132 can have operation duty-cycle operations (or duty-cycle operations) DC₁ and DC₂, respectively. Each duty-cycle operation DC₁ includes a combination of one active time interval (e.g., “ON” time interval) corresponding to T_{ON_1} and one inactive time interval (e.g., “OFF” time interval) T_{OFF_1}. Each duty-cycle operation (or duty-cycle operation) DC₂ includes a combination of one active time interval (e.g., “ON” time interval) corresponding to T_{ON_2} and one inactive time interval (e.g., “OFF” time interval) T_{OFF_2}. Based on the example above, duty-cycle operation DC₁ can be one hour (1 hr), and duty-cycle operation DC₂ can be ten hours (10 hrs). Thus, as shown in FIG. 2, resonator oscillator 131 is active more than resonator oscillator 132 in a given duty-cycle operation of the respective duty-cycle operation.

In the description herein, the described amounts of time (e.g., minutes or hours) used for time intervals T_{ON_1}, T_{OFF_1}, T_{ON_2}, and T_{OFF_2}, and duty-cycle operations DC₁ and DC₂ are only examples. Other amounts of time can be used.

FIG. 2 does not show duty-cycle operation of resonator oscillator 130 because resonator oscillator 130 is normally active (e.g., continuously active) during operation of apparatus 100. However, for comparison with resonator oscillators 131 and 132, resonator oscillator 130 is active more than each of resonator oscillators 131 and 132 for a given duty-cycle operation. Thus, resonator oscillator 130 ages faster than each of resonator oscillators 131 and 132.

FIG. 2 shows a specific number of duty-cycle operations DC₁ and DC₂ for simplicity. However, resonator oscillators 131 and 132 can have numerous duty-cycle operations like duty-cycle operations DC₁ and DC₂ shown in FIG. 2.

FIG. 2 shows an example where each of information CTL₁ and CTL₂ can be in the form of a signal, which can have different values (e.g., high (e.g., logic “1”) and low (e.g., logic “0”) levels) depending on the modes (active and inactive modes) of resonator oscillator 131 and resonator oscillator 132, respectively. FIG. 2 shows the value of the signal that represents information CTL₀ remains unchanged (e.g., remaining at a high signal level) to indicate that resonator oscillator 130 normally remains in an active mode. Resonator oscillator 130 may not enter an inactive mode while apparatus 100 is operating. Thus, as shown in FIG. 2, resonator oscillator 130 may not have a time interval like time interval T_{OFF_1} or T_{OFF_2}. Based on the duty-cycle operations DC₁ and DC₂ of resonator oscillators 131 and 132 shown in FIG. 2, apparatus 100 (FIG. 1) can operate to perform tracking aging of resonator oscillator 130.

As shown in FIG. 1, device 101 can include a frequency measurement circuitry 140, a code generator (e.g., a frequency correction code generator) 142, a timing signal generator 144, and internal circuitry 150. In the example where device 101 includes a processor (e.g., a hardware processor), internal circuitry 150 can be part of the processor (e.g., part of a CPU or a GPU of the processor). In the example where device 101 includes a memory device or a memory controller, internal circuitry 150 can be part of the memory device or the memory controller.

Frequency measurement circuitry 140 can include components (e.g., hardware (e.g., circuit elements), firmware, software, or any combination thereof) that can measure the frequency of signals like signals OSC₀, OSC₁, and OSC₂ and determine (e.g., calculate) deviations (e.g., differences) the frequencies of the signals. Part of components of frequency measurement circuitry 140 (e.g., part of hardware, firmware, software, or any combination thereof) can be included in (or provide by) control circuitry (e.g., control circuitry 135) of device 101. In apparatus 100, frequency measurement circuitry 140 can include input nodes coupled to respective nodes (e.g., output nodes) 110′, 111′, and 112′ of oscillator circuits 110, 111, and 112, respectively. Frequency measurement circuitry 140 can operate to measure the frequencies (F_{TGT}, F_{REF_1}, and F_{REF_2}) of signals oscillating signals OSC₀, OSC₁, and OSC₂ and determine (e.g., calculate) variations (e.g., frequency deviation) in relationships among frequencies F_{TGT}, F_{REF_1}, and F_{REF_2} and provide the results of the measurements (measurement results) at its output (e.g., output node or output nodes) 140′. The measure results can include a frequency deviation (measured frequency deviation) FD1 and a frequency deviation (measured frequency deviation) FD2.

Frequency deviation FD1 can be determined (e.g., calculate) as follow. For example, frequency measurement circuitry 140 can measure frequencies F_{TGT} and F_{REF_1} and provide frequency deviation FD1, where FD1=F_{TGT}−F_{REF_1} (a difference in values between F_{TGT} and F_{REF_1}). The term (measurement result) F_{TGT}−F_{REF_1} can be viewed an absolute frequency difference between frequency F_{TGT} and frequency F_{REF_1}. In another example, frequency measurement circuitry 140 can measure frequencies F_{TGT} and F_{REF_1} and provide a frequency deviation FD1, where FD1=(F_{TGT}−F_{REF_1})/F_{TGT}, or alternatively, FD1=(F_{TGT}−F_{REF_1})/F_{REF_1}. Each of the term (measurement result) (F_{TGT}−F_{REF_1})/F_{TGT} and the term (measurement result) (F_{TGT}−F_{REF_1})/F_{REF_1} can be viewed a relative frequency difference between frequency F_{TGT} and frequency F_{REF_1}. Thus, as described here, frequency deviation FD1 can be FD1=F_{TGT}−F_{REF_1}, FD1=(F_{TGT}−F_{REF_1})/F_{TGT}, or FD1=(F_{TGT}−F_{REF_1})/F_{REF_1}.

Frequency deviation FD2 can be determined (e.g., calculate) as follows. For example, frequency measurement circuitry 140 can measure frequencies F_{REF_1} and F_{REF_2} and provide frequency deviation FD2, where FD2=F_{REF_1}−F_{REF_2} (a difference in values between F_{REF_1} and F_{REF_2}). The term (measurement result) F_{REF_1}−F_{REF_2} can be viewed an absolute frequency difference between frequency F_{REF_1} and frequency F_{REF_2}. In another example, frequency measurement circuitry 140 can measure frequencies F_{REF_1} and F_{REF_2} and provide a frequency deviation FD2, where FD2=(F_{REF_1}−F_{REF_2})/F_{REF_1}, or alternatively, FD2=(F_{REF_1}−F_{REF_2})/F_{REF_2}. Each of the term (measurement result) (F_{REF_1}−F_{REF_2})/F_{REF_1} and the term (measurement result) (F_{REF_1}−F_{REF_2})/F_{REF_2} can be viewed a relative frequency difference between frequency F_{REF_1} and frequency F_{REF_2}. Thus, as described here, frequency deviation FD2 can be FD2=F_{REF_1}−F_{REF_2}, FD2=(F_{REF_1}−F_{REF_2})/F_{REF_1}, or FD2=(F_{REF_1}−F_{REF_2})/F_{REF_2}.

Code generator (e.g., frequency correction code generator) 142 can include components (e.g., hardware (e.g., circuit elements), firmware, software, or any combination thereof) to determine (e.g., calculate or alternatively estimate) a value for correction information (e.g., correction information CODE) based on measured frequency deviations (e.g., frequency deviations FD1 and FD2) provided by frequency measurement circuitry 140. Part of the components of code generator 142 (e.g., part of hardware, firmware, software, or any combination thereof) can be included in (or provided by) control circuitry (e.g., control circuitry 135) of device 101. The correction information generated by code generator 142 can have a value relative to value (e.g., known value) of a factor (e.g., multiplication factor “N”) in timing signal generator 144, so that the value of the correction information can be used to change (or to update) the value of such factor in timing signal generator 144. This can allow the frequency F_{OUT} of signal OSC_{OUT} at timing signal generator 144 to be changed (e.g., adjusted) to stay within a selected (e.g., predetermined) range based on the value of the correction information generated by code generator 142.

In apparatus 100, code generator 142 can include an input (e.g., input node or input nodes) coupled to output (e.g., output node or output nodes) 140′ of frequency measurement circuitry 140. Code generator 142 can receive and process frequency deviations FD1 and FD2. Based on frequency deviations FD1 and FD2, code generator 142 can generate correction information (e.g., a digital code) CODE and provided to its output (e.g., output node or output nodes) 142′. The value of correction information CODE can be based on the value of at least one (one or both) of frequency deviations FD1 and FD2.

Thus, as described above, code generator 142 can generate correction information CODE based on frequency deviation FD1. Since frequency deviation FD1 is generated based on a relationship between frequencies F_{TGT} and F_{REF_1} (e.g., FD1=F_{TGT}−F_{REF_1}, FD1=(F_{TGT}−F_{REF_1})/F_{TGT}, or FD1=(F_{TGT}−F_{REF_1})/F_{REF_1}), code generator 142 generates correction information CODE based on a relationship between frequencies F_{TGT} and F_{REF_1}. Similarly, as described above, code generator 142 can generate correction information CODE based on frequency deviations FD2. Since frequency deviation FD2 is generated based on a relationship between frequencies F_{REF_1} and F_{REF_2} (e.g., FD2=F_{REF_1}−F_{REF_2}, FD2=(F_{REF_1}−F_{REF_2})/F_{REF_1}, or FD2=(F_{REF_1}−F_{REF_2})/F_{REF_2}, code generator 142 generates correction information CODE based on a relationship between frequencies F_{REF_1} and F_{REF_2}.

Timing signal generator 144 can include a phase-locked loop (PLL) (e.g., a fractional-N PLL, an integer-N PLL, or other types of PLLs), a frequency-locked loop (FLL), a multiplying delay-locked loop (MDLL), or another circuitry that can operated to receive signal OSC_{TGT} and generate an oscillating signal (e.g., a clock signal) like signal OSC_{OUT}. As shown in FIG. 1, timing signal generator 144 can include an input (e.g., clock input node or clock input nodes) coupled to output node 110′ of oscillator circuit 110 to receive signal OSC_{TGT} generated by resonator oscillator 130. Timing signal generator 144 can generate signal OSC_{OUT} having a frequency F_{OUT} based on frequency F_{TGT} of signal OSC_{TGT}. Frequency F_{OUT} can be greater than frequency F_{TGT}.

Timing signal generator 144 include an input (e.g., control input node or control input nodes) coupled to output (e.g., output node or output nodes) 142′ of code generator 142 to receive correction information CODE from code generator 142. Timing signal generator 144 can be configured to adjust (e.g., change) frequency F_{OUT} based on correction information CODE. For example, timing signal generator 144 can include register circuitry to store control information (e.g., including multiplication factor “N”) in timing signal generator 144 to set frequency F_{OUT} at a target value (measures in Hertz units). Timing signal generator 144 can use correction information CODE to update control information (e.g., including updating multiplication factor “N”) in register circuitry in timing signal generator 144 with updated control information. Based on the updated control information, timing signal generator 144 can operate to adjust signal OSC_{OUT}, such that frequency F_{OUT} can be within a target frequency range. Thus, although frequency F_{TGT} of signal OSC_{TGT} generated by resonator oscillator 130 may change (e.g., drift) due to aging of resonator oscillator 130 (e.g., due to aging or resonator 120), the change frequency F_{TGT} of signal OSC_{TGT} may not impact frequency F_{OUT} of signal OSC_{OUT} because frequency F_{OUT} is adjust (corrected) based on correction information CODE, which is generated based on tracking of frequencies F_{REF_1} and F_{REF_2}.

The following description provides more detail of the operation of device 101 including scheme to track aging of resonator oscillator 130 and correct frequency F_{OUT} of signal OSC_{OUT} based on the tracking. In operation, control circuitry 135 can activate (e.g., at time T1 in FIG. 2) resonator oscillator 130 using information CTL₀ and allow resonator oscillator 130 to be in the active mode continuously (e.g., not to place resonator oscillator 130 in the inactive mode). Since resonator oscillator 130 is continuously in the active mode, it is continuously aging. This causes F_{TGT} of signal OSC_{TGT} to change (e.g., drift) over time. Control circuitry 135 can periodically activate (e.g., turn on) resonator oscillator 131 and 132 (using information CTL₁ and CTL₂, respectively) while resonator oscillator 130 is in the active mode (is turned on). For example, control circuitry 135 can periodically activate (e.g., turn on) resonator oscillator 131 based on duty-cycle operation of resonator oscillator 131 shown in FIG. 2. As an example, control circuitry 135 can periodically activate resonator oscillator 131 one minute (1 min) every one hour (1 hr). Thus, in this example, time interval T_{ON_1} in FIG. 2 is one minute (e.g., T_{ON_1}=1 min), and T_{OFF_1} is 59 minutes (e.g., T_{OFF_1}=59 min). Therefore, due to the duty-cycle operation in this example, resonator 121 has a much lower overall aging speed (e.g., aging rate) in comparison with resonator 120. In this example, resonator oscillator 131 has about 60 times (60×) lower aging speed than resonator oscillator 130.

In FIG. 1, frequency measurement circuitry 140 can measure frequencies F_{TGT} and F_{REF_1} when resonator oscillator 131 is in the active mode (e.g., turned on) and provide (e.g., calculate) frequency deviation FD1 (where FD1=F_{TGT}−F_{REF_1}). Frequency deviation FD1 can provides the knowledge of how much more resonator oscillator 130 has aged compared with resonator oscillator 131 during one duty-cycle interval (1 hour in this example) of resonator oscillator 131.

In operation, control circuitry 135 can periodically activate (e.g., turn on) resonator oscillator 132 while resonator oscillator 131 is in the active mode (is turned on) and while resonator oscillator 130 is active. However, control circuitry 135 may periodically activate resonator oscillator 132 less often than that of resonator oscillator 131. For example, control circuitry 135 can periodically activate (e.g., turn on) resonator oscillator 132 based on duty-cycle operation of resonator oscillator 132 shown in FIG. 2. As an example, control circuitry 135 can periodically activate resonator oscillator 132 one minute (1 min) every 10 hours (10 hr). Thus, in this example, time interval T_{ON_2} in FIG. 2 is one minute (e.g., T_{ON_2}=1 min), and T_{OFF_2} is 9 hours and 59 minutes (e.g., T_{OFF_2}=9 hr+59 min). Therefore, due to the duty-cycle operation in this example, resonator oscillator 132 has a lower overall aging speed (e.g., aging rate) in comparison with resonator oscillator 131 and a much lower overall aging speed (e.g., aging rate) in comparison with resonator oscillator 130. In this example, resonator oscillator 132 has about 10 times (10×) lower aging speed than resonator oscillator 131 and about 600 times (600× lower aging speed than resonator oscillator 130.

In FIG. 1, frequency measurement circuitry 140 can measure frequencies F_{TGT} and F_{REF_1} when resonator oscillators 131 and 132 are in the active mode (e.g., turned on) while resonator oscillator 130 is active. Frequency measurement circuitry 140 can provide (e.g., calculate) frequency deviation FD2 (where FD2=F_{REF_1}−F_{REF_2}). Frequency deviation FD2 provide the knowledge of how much more resonator oscillator 131 has aged compared with resonator oscillator 132 during one duty-cycle interval (10 hours in this example) of resonator oscillator 132.

As described above, code generator 142 can generate correction information (e.g., a digital code) CODE based on the values of frequency deviations FD1 and FD2 provided by frequency measurement circuitry 140. Timing signal generator 144 can change frequency F_{OUT} by changing the value of a factor (e.g., the multiplication factor “N”) in timing signal generator 144, such that frequency F_{OUT} can track the aging of resonator oscillators 131 and 132 instead of resonator oscillator 130. In an example, when resonator oscillators 130 and 131 are in the active mode (e.g., turned on) while resonator oscillator 132 is in the inactive mode (e.g., turned off), frequency F_{OUT} can be adjusted for aging based on the measurements of frequencies F_{TGT} and F_{REF_1} (e.g., based on the value of frequency deviation FD1), such that the aging of resonator oscillator 130 relative to the aging of resonator oscillator 131 can be determined (e.g., measured) and corrected. In another example, when resonator oscillators 130, 131, and 132 are in the active mode (e.g., turned on) frequency F_{OUT} can be adjusted for aging based on the measurements of frequencies F_{TGT}, F_{REF_1}, and F_{REF_2} (e.g., based on the value of frequency deviations FD1 and FD2), such that not only the aging of resonator oscillator 130 relative to the aging of resonator oscillator 131, but also the aging of resonator oscillator 131 relative to the aging of resonator oscillator 132 can be determined (e.g., measured) and corrected.

The above description provides an example where apparatus 100 includes two-level references in that resonator oscillators 131 and 132 are used as reference resonator oscillators to track aging of resonator oscillator 130. However, the aging tracking techniques described above can be applicable for more than two-level references. For example, in an alternative structure of apparatus 100, a fourth resonator oscillator can be added in the structure of apparatus 100. In such an alternative structure, the fourth resonator oscillator can be periodically activated (e.g., turned on) one minute every 100 hours (for example) to further reduce the effective aging time for frequency F_{OUT} by another 10× (10 times) after tracking.

The following description provides additional techniques for tracking aging of resonator 120. As described above, both resonator oscillators 131 and 132 can be used as a reference resonator oscillator to track aging of resonator 120 based on frequency deviation FD1 (where FD1=F_{TGT}−F_{REF_1}, FD1=(F_{TGT}−F_{REF_1})/F_{TGT}, or FD1=(F_{TGT}−F_{REF_1})/F_{REF_1}) and frequency deviation FD2 (FD2=F_{TGT}−F_{REF_1}, FD2=(F_{REF_1}−F_{REF_2})/F_{REF_1}, or FD2=(F_{REF_1}−F_{REF_2})/F_{REF_2}). The following examples provide more details for aging correction for resonator oscillator 131 and aging correction for resonator oscillator 130.

For example, when both resonator oscillators 131 and 132 are in the active modes (e.g., between times T11 and T11′ and between times T21 and T21′ in FIG. 2), device 101 can track resonator oscillator 131 to its own reference, which is resonator oscillator 132. Since signal OSC₁ is not provided to timing signal generator 144 (as shown in FIG. 1), physically correction of frequency F_{REF_1} of signal OSC₁ based on the operation of timing signal generator 144 may not be performed. However, a “virtual” correction of frequency F_{REF_1} can be performed to provide a corrected frequency F′_{REF_1} (which is a “virtually” corrected frequency of signal OSC₁). In this example, frequency deviation FD1′=F_{REF_1}−F′_{REF_1} can be calculated (e.g., by frequency measurement circuitry 140) and stored (e.g., recorded). However, frequency deviation FD1′ may not be applied to signal OSC₁. Frequency deviation FD1′=F_{REF_1}−F′_{REF_1} is used as an example. However, frequency deviation FD1′ can be calculated based on other relative frequency differences between frequency F_{REF_1} and F′_{REF_1}.

In another example, when only resonator oscillator 131 is in the active mode (e.g., between times T2 and T2′), device 101 can track resonator oscillator 130 to its direct reference resonator oscillator 131. Rather than using frequency F_{REF_1} as a reference, frequency F′_{REF_1} (result of resonator oscillator 131 aging tracking from its reference resonator oscillator 132) can be used and to set frequency F_{OUT} by using frequency deviation FD1 and the stored frequency deviation FD1′ (e.g., FD1′=F_{REF_1}−F′_{REF_1}).

A correction algorithm can be formed to directly reset frequencies F_{TGT} and F_{REF_1} towards their respective references. This means that in part frequency F′_{REF_1} can be set (set virtually and stored in the system) to be the same as frequency F_{REF_2} when FD2 is calculated (as described above). Frequency F_{OUT} can be set to be the same as frequency F′_{REF_1} when FD1 is calculated (as described above).

However as compared with frequency F_{REF_2}, the timing error of frequency F_{OUT} may still exist, even though frequency F_{REF_2} is the eventual tracking target in this two-level referencing scheme. For example, the timing error of frequency F_{OUT} may still exist because there is still some small timing error accumulated in between two correction events (e.g., between time interval T1′ and T2′ or between times T2′ and T3) although the frequency error has been reset in each event, and those timing errors may still accumulate over time.

The following description provide a scheme (e.g., an algorithm) to improve on the accumulated timing error after aging tracking, discussed above. The following techniques can compensate estimated timing error by introducing an intended frequency error. The scheme involves estimating and updating the accumulated timing error at each correction event (e.g., one time every 1 hour in the example of FIG. 2) and adjust the frequency of the signal output from the resonator oscillators (not necessarily forcing frequency error to be zero) accordingly for the next cycle, such that projected accumulated timing error at next correction event can be compensated to zero. The scheme described here can include the following. The scheme can include calculating a timing error estimation at each correction event. The timing error estimation can be based on the past measurements of frequency deviations FD1 and FD2. Since the measurement is performed at the correction event, the frequency deviations FD1 and FD2 is like a sampled data. Thus, to calculate timing error from frequency variations caused by aging, the scheme can assume certain behavior for the aging characteristic between two sampling moments. For example, it can be assumed that the relative aging rate among a pair of resonator oscillators (e.g., resonator oscillators 130 and 131, and resonator oscillators 131 and 132) in between two correction events (e.g., one hour in this example of FIG. 2) is linear. The linear aging assumption described above is for simplification purpose and used as an example for demonstration here. However, a higher order aging model can also be adopted to achieve better timing error estimation from frequency measurements obtained in a sampled manner (one sample per hour in this example).

After the accumulated timing error is estimated and updated at the correction event, the scheme can include adjusting F_{OUT} and F′_{REF_1}, respectively, by intentionally introducing a frequency error. The frequency error can be introduced, such that the additional accumulated timing error from one correction event (e.g., a current correction event) to the next correction event (again assuming linear aging for resonator oscillators) can compensate for the estimated timing error in the past. This can be viewed as trying to achieve a zero projected timing error at the next correction event.

The timing error estimation can subsequently be updated again at the next correction event. The scheme can repeat calculating a timing error estimation at the next correction event, as described above, to continue this aging tracking process.

Thus, as described above, the inclusion of multiple resonators (e.g., an array of resonators like resonators 120, 121, and 122), instead of only one resonator, allows apparatus 100 to have multiple resonator oscillators (e.g., multiple crystal oscillators 130, 131, and 132). The multiple resonator oscillators allow different ways (as described above) for tracking aging of a selected resonator oscillator that is used to generate a timing signal (e.g., signal OSC_{OUT}) for used in circuitry (e.g., used in internal circuitry 150) of device 101. As described above, the tracking of aging provides an improved solution for maintaining accuracy of timing in electronic devices and systems (e.g., apparatus 100 in FIG. 1 and system 300 in FIG. 3).

FIG. 3 shows an apparatus in the form of a system (e.g., electronic system) 300, according to some embodiments described herein. System 300 can be viewed as a machine. System (e.g., machine) 300 can include or be included in a computer, a cellular phone, or other electronic systems. As shown in FIG. 3, system 300 can include components (e.g., devices) located on a circuit board (e.g., PCB) 302. The components can include a processor (e.g., a hardware processor) 315, a memory device 320, a memory controller 330, a graphics controller 340, an input and output (I/O) controller 350, a display 352, a keyboard 354, a pointing device 356, at least one antenna 358, a storage device 360, and a bus 370. Bus 370 can include conductive lines (e.g., metal-based traces on a circuit board 302 where the components of system 300 are located).

System 300 may be configured to perform one or more of the methods and/or operations described herein. At least one of the components of system 300 (e.g., at least one of processor 315, memory device 320, memory controller 330, graphics controller 340, and I/O controller 350) can include device 101 of FIG. 1.

In FIG. 3, processor 315 can include a general-purpose processor or an application specific integrated circuit (ASIC). Processor 315 can include a central processing unit (CPU) and processing circuitry. Graphics controller 340 can include a graphics processing unit (GPU) and processing circuitry. Memory device 320 can include a dynamic random-access memory (DRAM) device, a static random-access memory (SRAM) device, a flash memory device, phase change memory, or a combination of these memory devices, or other types of memory. FIG. 3 shows an example where memory device 320 is a stand-alone memory device separated from processor 315. In an alternative structure, memory device 320 and processor 315 can be located on the same integrated circuit (IC) chip (e.g., a semiconductor die or IC die). In such an alternative structure, memory device 320 is an embedded memory in processor 315, such as embedded DRAM (eDRAM), embedded SRAM (eSRAM), embedded flash memory, or another type of embedded memory.

Storage device 360 can include drive unit (e.g., hard disk drive (HID), solid-state drive (SSD), or another mass storage device). Storage device 360 can include a machine-readable medium 362 and processing circuitry. Machine-readable medium 362 can store one or more sets of data structures or instructions 364 (e.g., software) embodying or used by any one or more of the techniques or functions described herein. Instructions 364 may also reside, completely or at least partially, within memory device 320, memory controller 330, processor 315, or graphics controller 340 during execution thereof by system (e.g., machine) 300.

In an example, one of (or any combination of) processor 315, memory 320, memory controller 330, graphics controller 340, and storage device 360 may constitute machine-readable media. Non-limiting machine-readable medium examples may include solid-state memories and optical and magnetic media. Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 3 shows machine-readable medium 362 as a single medium as an example. However, the term “machine-readable medium” may include a single medium or multiple media (e.g., a centralized or distributed database, and/or associated caches and servers) configured to store instructions 364. Further, the term “machine-readable medium” may include any medium that is capable of storing, encoding, or carrying instructions for execution by system 300 and that causes system 300 to perform any one or more of the techniques of the present disclosure, or that is capable of storing, encoding or carrying data structures used by or associated with such instructions. In some examples, machine-readable media may include non-transitory machine-readable media. In some examples, machine-readable media may include machine-readable media that is not a transitory propagating signal.

Display 352 can include a liquid crystal display (LCD), a touchscreen (e.g., capacitive or resistive touchscreen), or another type of display. Pointing device 356 can include a mouse, a stylus, or another type of pointing device. In some structures, system 300 does not have to include a display. Thus, in such structures, display 352 can be omitted from system 300.

Antenna 358 can include one or more directional or omnidirectional antennas, including, for example, dipole antennas, monopole antennas, patch antennas, loop antennas, microstrip antennas, or other types of antennas suitable for transmission of radio frequency (RF) signals. In some structures, system 300 does not have to include an antenna. Thus, in such structures, antenna 358 can be omitted from system 300.

I/O controller 350 can include a communication module for wired or wireless communication (e.g., communication through one or more antennas 358). Such wireless communication may include communication in accordance with WiFi communication technique, Long Term Evolution Advanced (LTE-A) communication technique, or other communication techniques.

I/O controller 350 can also include a module to allow system 300 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 355 can include terminals (e.g., pins) to allow system 300 to receive a connection (e.g., an electrical connection) from an external device (or system). This may allow system 300 to communicate (e.g., exchange information) with such a device (or system) through connector 355. Connector 355 and at least a portion of bus 370 can include conductive lines that conform with at least one of USB, DP, HDMI, Thunderbolt, PCIe, Ethernet, and other specifications.

FIG. 3 shows the components (e.g., devices) of system 300 arranged separately from each other as an example. For example, each of processor 315, memory device 320, memory controller 330, graphics controller 340, and I/O controller 350 can be included in (e.g., formed in or formed on) a separate integrated circuit (IC) chip (e.g., separate semiconductor die or separate IC die). In some structures of system 300, two or more components (e.g., processor 315, memory device 320, graphics controller 340, and I/O controller 350) of system 300 can be included in (e.g., formed in or formed on) the same IC chip (e.g., same semiconductor die), forming an SoC, or alternatively, an SiP.

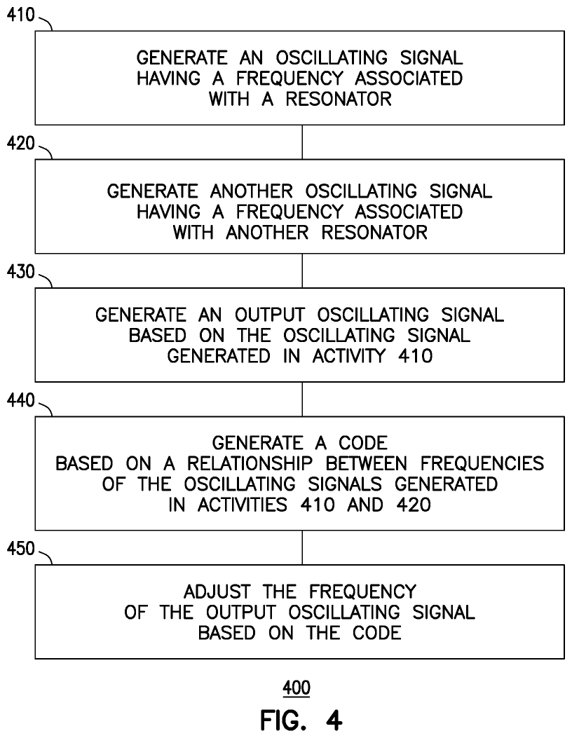

FIG. 4 is a flowchart showing a method 400 of tracking aging of resonator oscillator, according to some embodiments described herein. The method 400 can be performed by any of the apparatuses (e.g., device 101 and system 300) described above with reference to FIG. 1 through FIG. 3. Some of the activities in method 400 may be performed by hardware, software, firmware, or any combination of hardware, software, and firmware of a device (e.g., device 101, processor 315, memory device 320, memory controller 330, graphics controller 340, or I/O controller 350 of system 300) or a system (e.g., system 300).

As shown in FIG. 4, method 400 can include activities (e.g., operations) 410, 420, 430, 440, and 450. Activity 410 can include generating an oscillating signal having a frequency associated with a resonator. For example, the oscillating signal generated in activity 410 can include signal OSC_{TGT} (FIG. 1) associated with resonator 120 (FIG. 1). Activity 420 can include generating another oscillating signal having a frequency associated with another resonator. For example, the oscillating signal generated in activity 420 can include signal OSC₁ (FIG. 1) associated with resonator 121 (FIG. 1). Activity 430 can include generating a code based on a relationship between the frequencies of the oscillating signals generated in activities 410 and 420. For example, the code generated in activity 430 can include information CODE generated by code generator 142 (FIG. 1) based on a measured frequency deviations (e.g., frequency deviation FD1, FD2, or both) generated by frequency measurement circuitry 140 (FIG. 1). Activity 440 can include generating an output oscillating signal having a frequency based on the frequency of the oscillating signal generated in activity 410. For example, the output oscillating signal generated in activity 440 can include signal OSC_{OUT} (FIG. 1). Activity 450 can include adjusting the frequency of the output oscillating signal based on the code. For example, timing signal generator 144 (FIG. 1) can adjust frequency F_{OUT} of signal OSC_{OUT} based on information CODE from code generator 142 (FIG. 1).

Method 400 described above can include fewer or more activities relative to activities 410, 420, 430, 440, and 450 in FIG. 4. For example, method 400 can include activities and operations of the apparatuses (e.g., device 101 and system 300) described above with reference to FIG. 1 through FIG. 3. Thus, method 400 can have improvements and benefits similar to those of apparatus 100.

The illustrations of the apparatuses (e.g., apparatus 100 (including device 101) and system 300) described and methods (e.g., operations of device 101 and system 300, and methods 400) described above are intended to provide a general understanding of the structure of different embodiments and are not intended to provide a complete description of all the elements and features of an apparatus that might make use of the structures described herein. An apparatus herein refers to, for example, either a device (e.g., device 101, processor 315, memory device 320, memory controller 330, graphics controller 340, or I/O controller 350), a system (e.g., system 300), or a machine (e.g., system 300).

Any of the components described above with reference to FIG. 1 through FIG. 4 can be implemented in a number of ways, including simulation via software. Thus, apparatuses described above may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The apparatuses and methods described above can include or be included in high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

In the detailed description and the claims, the terms “first,” “second,” and “third,” etc. are used merely as labels, and are not intended to impose numerical requirements on their objects.

In the detailed description and the claims, the term “adjacent” refers to a position of a thing being next to (e.g., either immediately next to or close to with one or more things between them) or adjoining another thing (e.g., abutting it or contacting it (e.g., directly coupled to) it).

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

Described implementations of the subject matter can include one or more features, alone or in combination as illustrated below by way of examples.

Example 1 is apparatus comprising: a first oscillator circuit including a first input node to receive a connection from a first resonator, and a first output node to provide a first oscillating signal, a second oscillator circuit including a second input node to receive a connection from a second resonator, and a second output node to provide a second oscillating signal, a frequency measurement circuitry coupled to the first output node and the second output node, a code generator including an input node coupled to an output node of the frequency measurement circuitry, and an output node to provide a code, and a timing signal generator including a node coupled to the output node of the code generator, an input node coupled to the output node of the first oscillator circuit, and an output node to provide an output oscillating signal.

In Example 2, the subject matter of Example 1 includes subject matter wherein the first resonator and the second resonator have a same resonator type.

In Example 3, the subject matter of Example 1 includes subject matter wherein each of the first resonator and the second resonator includes a quartz crystal.

In Example 4, the subject matter of any of Examples 1-2 includes subject matter wherein each of the first and second resonators includes a ceramic resonator.

In Example 5, the subject matter of any of Examples 1-2 includes subject matter wherein each of the first resonator and the second resonator includes an LC (inductor-capacitor) circuit.

In Example 6, the subject matter of Example 1 includes, a third oscillator circuit, the third oscillator circuit including a third input node to receive a connection from a third resonator, and a third output node to provide a third oscillating signal.

In Example 7, the subject matter of Example 6 includes subject matter wherein each of the first resonator, the second resonator, and the third resonator includes a quartz crystal.

In Example 8, the subject matter of any of Examples 6-7 includes subject matter wherein the frequency measurement circuitry is to measure a first frequency of the first oscillating signal and a second frequency of the second signal while the third oscillator circuit is inactive, and the code generator is to generate the code based on a relationship between the first frequency and the second frequency.

In Example 9, the subject matter of any of Examples 6-7 includes subject matter wherein the frequency measurement circuitry is to measure a first frequency of the first oscillating signal and a second frequency of the second signal while the third oscillator circuit is inactive, and the code generator is to generate the code based on a frequency difference between the first frequency and the second frequency.

In Example 10, the subject matter of any of Examples 1-9 includes subject matter wherein the code generator is to generate the code based on a difference between a frequency of the first oscillating signal and a frequency of the second oscillating signal.

In Example 11, the subject matter of any of Examples 1-9 includes subject matter wherein the code generator is to generate the code based on a relationship between a frequency of the first oscillating signal and a frequency of the second oscillating signal.

In Example 12, the subject matter of any of Examples 1-9 includes subject matter wherein the code generator is to generate the code based on the relationship between the frequency of the first oscillating signal and the frequency of the second oscillating signal, and a relationship between the frequency of the second oscillating signal and the frequency of the third oscillating signal.

In Example 13, the subject matter of any of Examples 1-12 includes subject matter wherein the apparatus comprises as system in a package (SiP), the SiP including an integrated circuit (IC) chip, wherein the first oscillator circuit, the second oscillator circuit, the frequency measurement circuitry, the code generator, and the timing signal generator are included in the IC, the first resonator is coupled to the first input node, and the first resonator is part of the SiP and located outside the IC chip, and the second resonator is coupled to the second input node, and the second resonator is part of the SiP and located outside the IC chip.

In Example 14, the subject matter of any of Examples 1-12 includes, a circuit board and an integrated circuit (IC) located on the circuit board, wherein the first oscillator circuit, the second oscillator circuit, the frequency measurement circuitry, the code generator, and the timing signal generator are included in the IC chip, and the first resonator and the second resonator are located outside the IC chip and located on the circuit board.

In Example 15, the subject matter of any of Examples 1-12 includes, a processor, the processor including the first oscillator circuit, the second oscillator circuit, the frequency measurement circuitry, the code generator, and the timing signal generator.

In Example 16, the subject matter of any of Examples 1-5 includes subject matter wherein the timing signal generator includes a phase-locked loop.

Example 17 is an apparatus comprising: a first oscillator circuit to generate a first oscillating signal having a first frequency associated with a first resonator, a second oscillator circuit to generate a second oscillating signal having a second frequency associated with a second resonator, a code generator to generate a code based on a relationship between the first frequency and the second frequency, and a timing signal generator to receive the first oscillating signal and generate an output signal having an output frequency based on the first frequency, and the timing signal generator including an input node to receive the code and adjust the output frequency based on the code.

In Example 18, the subject matter of Example 17 includes, a third oscillator circuit to generate a third oscillating signal having a third frequency associated with a third resonator, wherein the code generator is to generate the code based on the relationship between the first frequency and the second frequency and based on a relationship between the second frequency and the third frequency.

In Example 19, the subject matter of Example 18 includes subject matter wherein each of the first resonator, the second resonator, and the third resonator includes a quartz crystal.

In Example 20, the subject matter of Example 17 includes subject matter wherein each of the first and second resonators includes a ceramic resonator.

In Example 21, the subject matter of Example 17 includes subject matter wherein each of the first and second resonators includes an LC (inductor-capacitor) circuit.

In Example 22, the subject matter of Example 18 includes, control circuitry to activate the first oscillator circuit, periodically activate the second oscillator circuit while the first oscillator circuit is activated, and periodically activate the third oscillator circuit while the first oscillator circuit is activated.

In Example 23, the subject matter of Example 19 includes subject matter wherein the control circuitry is to deactivate the third oscillator circuit while the first oscillator circuit is activated and while the second oscillator circuit is activated.

In Example 24, the subject matter of Example 18 includes subject matter wherein the control circuitry is to activate the first oscillator circuit, periodically turn on the second oscillator circuit for a first time interval while the first oscillator circuit is activated and turn off the second oscillator circuit for a second time interval while the first oscillator circuit is activated, periodically turn on the third oscillator circuit for a third time interval while the first oscillator circuit is activated and turn off the second oscillator circuit for a fourth time interval while the first oscillator circuit is activated, and wherein the second time interval is less than the fourth time interval.

In Example 25, the subject matter of any of Examples 1-24 includes subject matter wherein the timing signal generator includes a phase-locked loop.

In Example 26, the subject matter of any of Examples 1-25 includes subject matter wherein the apparatus comprises as system-on-chip (SoC), the SoC including an IC chip, wherein the first oscillator circuit, the second oscillator circuit, the frequency measurement circuitry, the code generator, and the timing signal generator are included in an integrated circuit (IC) chip.

In Example 27, the subject matter of any of Examples 1-25 includes, a connector and an integrated circuit (IC) chip coupled to the connector, the IC chip including the first oscillator circuit, the second oscillator circuit, the code generator, and the timing signal generator, wherein the connector conforms with at least one of Universal Serial Bus (USB), High-Definition Multimedia Interface (HDMI), Thunderbolt, Peripheral Component Interconnect Express (PCIe), and Ethernet specifications.

Example 28 is method comprising: generating a first oscillating signal having a first frequency associated with a first resonator, generating a second oscillating signal having a second frequency associated with a second resonator, generating a code based on a relationship between the first frequency and the second frequency, generating an output signal having a frequency based on the first frequency, and adjusting the frequency of the output signal based on the code.

In Example 29, the subject matter of Example 28 further comprising generating a third oscillating signal having a third frequency associated with a third resonator, and generating the code based on the relationship between the first frequency and the second frequency and based on a relationship between the second frequency and the third frequency.

In Example 30, the subject matter of Example 29, further comprising activating a first oscillator circuit to generate the first oscillating signal, activating a second oscillator circuit to generate the second oscillating signal while the first oscillator circuit is activated, deactivating the second oscillator circuit while the first oscillator circuit is activated, activating a third oscillator circuit to generate the third oscillating signal while the first oscillator circuit is activated and while the second oscillator circuit is activated during a first time interval, and deactivating the third oscillator circuit while the first oscillator circuit is activated and while the second oscillator circuit is activated during a second time interval.

In Example 31, the subject matter of Example 30, further comprising periodically activating and deactivating the second oscillator circuit while the third oscillator circuit is deactivated.

In Example 32, the subject matter of Example 31 includes subject matter wherein the second oscillator circuit is deactivated for a first time interval, third oscillator circuit is deactivated for a second time interval, wherein the first time interval is less than the second time interval.

In Example 33, the subject matter of any of Examples 28-32, further comprising measuring the first frequency, the second frequency, and the third frequency, generating a first value based on a relationship between the first frequency and the second frequency, generating a second value based on a relationship between the second frequency and the third frequency, and generating the code based the first value and the second value.

Example 34 is at least one a machine-readable medium including instructions that, when executed by processing circuitry, cause the processing circuitry to perform operations to implement any of Examples 1-33.

Example 35 is an apparatus comprising means to implement any of Examples 1-33.

Example 36 is system to implement any of Examples 1-33.

Example 37 is a method to implement any of Examples 1-33.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a first oscillator circuit including a first input node to receive a connection from a first resonator, and a first output node to provide a first oscillating signal;
a second oscillator circuit including a second input node to receive a connection from a second resonator, and a second output node to provide a second oscillating signal;
a frequency measurement circuit coupled to the first output node and the second output node;
a code generator including an input node coupled to an output node of the frequency measurement circuit, and an output node to provide a code; and
a timing signal generator including a node coupled to the output node of the code generator, an input node coupled to the output node of the first oscillator circuit, and an output node to provide an output oscillating signal.

2. The apparatus of claim 1, wherein the first resonator and the second resonator have a same resonator type.

3. The apparatus of claim 1, wherein each of the first resonator and the second resonator includes a quartz crystal.

4. The apparatus of claim 1, further comprising a third oscillator circuit, the third oscillator circuit including a third input node to receive a connection from a third resonator, and a third output node to provide a third oscillating signal.

5. The apparatus of claim 4, wherein each of the first resonator, the second resonator, and the third resonator includes a quartz crystal.

6. The apparatus of claim 1, wherein the code generator is to generate the code based on a relationship between a frequency of the first oscillating signal and a frequency of the second oscillating signal.

7. The apparatus of claim 1, wherein the apparatus comprises as system in a package (SiP), the SiP including an integrated circuit (IC) chip, wherein:
the first oscillator circuit, the second oscillator circuit, the frequency measurement circuit, the code generator, and the timing signal generator are included in the IC chip;
the first resonator is coupled to the first input node, and the first resonator is part of the SiP and located outside the IC chip; and
the second resonator is coupled to the second input node, and the second resonator is part of the SiP and located outside the IC chip.

8. The apparatus of claim 1, further comprising a circuit board and an integrated circuit (IC) located on the circuit board, wherein:
the first oscillator circuit, the second oscillator circuit, the frequency measurement circuit, the code generator, and the timing signal generator are included in the IC chip; and
the first resonator and the second resonator are located outside the IC chip and located on the circuit board.

9. The apparatus of claim 1, further comprising a processor, the processor including the first oscillator circuit, the second oscillator circuit, the frequency measurement circuit, the code generator, and the timing signal generator.

10. An apparatus comprising:
a first oscillator circuit to generate a first oscillating signal having a first frequency associated with a first resonator;
a second oscillator circuit to generate a second oscillating signal having a second frequency associated with a second resonator;
a code generator to generate a code based on a relationship between the first frequency and the second frequency; and
a timing signal generator to receive the first oscillating signal and generate an output signal having an output frequency based on the first frequency, the timing signal generator including an input node to receive the code and adjust the output frequency based on the code.

11. The apparatus of claim 10, further comprising a third oscillator circuit to generate a third oscillating signal having a third frequency associated with a third resonator, wherein:
the code generator is to generate the code based on the relationship between the first frequency and the second frequency and based on a relationship between the second frequency and the third frequency.

12. The apparatus of claim 11, wherein each of the first resonator, the second resonator, and the third resonator includes a quartz crystal.

13. The apparatus of claim 11, further comprising control circuitry to:
activate the first oscillator circuit;
periodically activate the second oscillator circuit while the first oscillator circuit is activated; and
periodically activate the third oscillator circuit while the first oscillator circuit is activated.

14. The apparatus of claim 13, wherein the control circuitry is to:
deactivate the third oscillator circuit while the first oscillator circuit is activated and while the second oscillator circuit is activated.

15. The apparatus of claim 11, wherein the control circuitry is to:
activate the first oscillator circuit;
periodically turn on the second oscillator circuit for a first time interval while the first oscillator circuit is activated and turn off the second oscillator circuit for a second time interval while the first oscillator circuit is activated;
periodically turn on the third oscillator circuit for a third time interval while the first oscillator circuit is activated and turn off the second oscillator circuit for a fourth time interval while the first oscillator circuit is activated; and
wherein the second time interval is less than the fourth time interval.

16. The apparatus of claim 10, further comprising a connector and an integrated circuit (IC) chip coupled to the connector, the IC chip including the first oscillator circuit, the second oscillator circuit, the code generator, and the timing signal generator, wherein the connector conforms with at least one of Universal Serial Bus (USB), High-Definition Multimedia Interface (HDMI), Thunderbolt, Peripheral Component Interconnect Express (PCIe), and Ethernet specifications.

17. A method comprising:
generating a first oscillating signal having a first frequency associated with a first resonator;
generating a second oscillating signal having a second frequency associated with a second resonator;
generating a code based on a relationship between the first frequency and the second frequency;
generating an output signal having a frequency based on the first frequency; and
adjusting the frequency of the output signal based on the code.

18. The method of claim 17, further comprising:
generating a third oscillating signal having a third frequency associated with a third resonator; and
generating the code based on the relationship between the first frequency and the second frequency and based on a relationship between the second frequency and the third frequency.

19. The method of claim 18, further comprising:
activating a first oscillator circuit to generate the first oscillating signal;
activating a second oscillator circuit to generate the second oscillating signal while the first oscillator circuit is activated;
deactivating the second oscillator circuit while the first oscillator circuit is activated;
activating a third oscillator circuit to generate the third oscillating signal while the first oscillator circuit is activated and while the second oscillator circuit is activated during a first time interval; and
deactivating the third oscillator circuit while the first oscillator circuit is activated and while the second oscillator circuit is activated during a second time interval.

20. The method of claim 19, further comprising:
measuring the first frequency, the second frequency, and the third frequency;
generating a first value based on a relationship between the first frequency and the second frequency;
generating a second value based on a relationship between the second frequency and the third frequency; and
generating the code based the first value and the second value.
